(19) United States
(12) Patent Application Publication
(10) Pub. No.: US 2011/0215288 A1
(43) Pub. Date: Sep. 8, 2011

(54) SEMICONDUCTOR STORAGE DEVICE AND MANUFACTURING METHOD THEREOF

(75) Inventors: Yuichi MATSUI, Kawasaki (JP); Tomio IWASAKI, Tsukuba (JP); Norikatsu TAKAURA, Tokyo (JP); Kenzo KUROTSUCHI, Kokubunji (JP)

(73) Assignee: RENESAS ELECTRONICS CORPORATION, Kanagawa (JP)

(21) Appl. No.: 13/108,174

(22) Filed: May 16, 2011

Related U.S. Application Data
(63) Continuation of application No. 11/435,934, filed on May 18, 2006.

(30) Foreign Application Priority Data
May 19, 2005 (JP) 2005-146387
Mar. 31, 2006 (JP) 2006-096616

(51) Int. Cl. H01L 45/00

(52) U.S. Cl. 257/2; 257/E45.001

(57) ABSTRACT

Since a chalcogenide material has low adhesion to a silicon oxide film, there is a problem in that it tends to separate from the film during the manufacturing step of a phase change memory. In addition, since the chalcogenide material has to be heated to its melting point or higher during resetting (amorphization) of the phase change memory, there is a problem of requiring extremely large rewriting current. An interfacial layer includes an extremely thin insulator or semiconductor having the function as both an adhesive layer and a high resistance layer (thermal resistance layer) is inserted between chalcogenide material layer/interlayer insulative film and between chalcogenide material layer/plug.

This is a continuation application of U.S. application Ser. No. 11/435,934, filed May 18, 2006, the contents of which are hereby incorporated by reference into this application.

### CLAIM OF PRIORITY

The present application claims priority from Japanese application JP2005-146387, filed on May 19, 2005, and Japanese application JP2006-096616, filed on Mar. 31, 2006, the contents of which are hereby incorporated by reference into this application.

### BACKGROUND OF THE INVENTION

1. Field of the Invention

The present invention relates to a semiconductor storage device and a manufacturing method thereof and it particularly relates to a technique effectively applied to a semiconductor integrated circuit device having a phase change memory cell formed by using a phase changing material such as chalcogenide.

2. Description of the Related Arts

Semiconductor memories such as DRAMs, SRAMs, and FLASH memories have been used for mobile equipment typically represented by mobile telephones. While DRAMs have a large capacity, the access speed thereof is low. On the other hand, while SRAMs have a high speed, since they require many transistors such as by the number of 4 to 6 per one cell, higher integration is difficult and they are not suitable to large capacity memories. Further, it is necessary to always supply current for retaining data in DRAMs and SRAMs (volatility). On the other hand, since the FLASH memories are nonvolatile, current supply for electrically retaining memory are not required. However, they involve a drawback that the number of cycles for rewriting and erasure is finite as about 10⁵ times and the speed for rewriting is slower by about several digit compared with other memories. As described above, the memories have merits and demerits and they are used selectively in accordance with the features at present.

In a case where a universal memory having respective merits of DRAM, SRAM, and FLASH memory together is achieved, a plurality of memories can be united into a single chip to further decrease the size and increase the function of mobile telephones and various kinds of other mobile equipment. In addition, in a case where all of the semiconductor memories can be replaced therewith, this will give a significant impact. The matters required for the universal memory includes, for example, (1) high degree of integration (high capacity) comparable with DRAM, (2) high speed access (writing/reading) comparable with SRAM, (3) nonvolatility comparable with FLASH memory, (4) low power consumption capable of coping with small-sized battery driving.

Among the nonvolatile memories in the next generation referred to as the universal memory, a phase change memory has most attracted attention at present. The phase change memory uses a chalcogenide material used in optical disks such as CD-RW and DVD, and stores data depending on the difference between the crystalline state and the amorphous state in the same manner. The difference resides in the writing/reading method. While transmission or reflection of light is utilized as typically represented by a laser in an optical disk, writing is conducted by Joule heat generated by current and signals is read due to the difference of the resistance value by the phase change in the phase change memory.

The operation principle of the phase change memory (abbreviation of semiconductor memory device here and hereinafter) is to be described with reference to FIG. 2. In a case of amorphization of a chalcogenide material, a reset pulse of heating a chalcogenide material to a melting point or higher, and then quenching the same is applied. The melting point is, for example, at 600° C. The quenching time (t1) is, for example, 2n sec. In a case of crystallizing the chalcogenide material, a set pulse of retaining the temperature of the chalcogenide material to a crystallizing temperature or higher and melting point or lower is applied. The crystallization temperature is, for example, 400° C. The time (t2) required for crystallization is, for example, 50n sec.

The phase change memory has a feature that the reading can be conducted at a high speed. Since a resistance value of the chalcogenide material changes by as much as 2 to 3 digits in accordance with the state of crystallization and the resistance value is used as the signal, so that the reading signal is large and the sensing operation is facilitated. In addition, it has a function capable of rewriting 10¹² times, which can compensate for the drawback of the FLASH memory. Further, the feature capable of operating at low voltage and low power and capable of being easily embedded with a logic circuit makes it suitable for use in mobile equipment.

An example of a step of manufacturing a phase change memory cell is to be described simply with reference to cross sectional step charts for a main portion in FIGS. 3 to 5.

Referring at first to FIG. 3, a selection transistor is formed by a well-known manufacturing method on a not illustrated semiconductor substrate. The selection transistor comprises, for example, an MOS transistor or a bipolar transistor. Then, by using a well-known manufacturing method, an inter-layer insulative film 1 comprising, for example, a silicon oxide film is deposited and a plug 2 comprising, for example, tungsten is formed in the interlayer insulative film 1. The plug has a function of electrically connecting the selection transistor located on a lower side and the phase changing material layer located on an upper side. Then, a chalcogenide material layer 3 comprising, for example, GeSbTe, an upper electrode 4 comprising, for example, tungsten and a hard mask 5 comprising, for example, a silicon oxide film are deposited successively as shown in FIG. 3.

Then, as shown in FIG. 4, the hard mask 5, the upper electrode 4, and the chalcogenide material layer 3 are fabricated successively by a well-known lithographic method and dry etching method.

Then, an inter-layer insulative film 6 is deposited as shown in FIG. 5. Then, an interconnection layer for electric connection with the upper electrode 4 and, further, a plurality of interconnection layers (not illustrated) are formed further above the inter-layer insulative film 6. A phase change memory cell is substantially completed by the steps described above. Those concerned with the phase change memory cell of this type include Technical Digest of International Electron Device Meeting, 2001, pp 803-806 and those concerned with the phase change of the chalcogenide material include Journal of Applied Physics, vol. 87, No. 9, May 2000, p 4130.

### SUMMARY OF THE INVENTION

The present invention clarifies a problem in the manufacturing step of a phase change memory and a problem in the rewriting operation of the phase change memory and provides means capable of solving the problems at the same time. Two problems to be solved are to be described successively.

A first problem is that a film tends to separate from a substrate during a manufacturing step of a phase change memory since the chalcogenide material has low adhesion. In particular, since the chalcogenide material has low adhesion with a silicon oxide film, it is necessary to provide an adhesion layer between the chalcogenide material layer and the inter-layer insulative film.

In the phase change memory, it has already been known that the insertion of an adhesion layer is effective in preventing peeling of the chalcogenide material layer. Known examples include, for example, JP-A No. 2003-1741144 (Patent Document 1), USP No. 2004/0026731 (Patent Document 2), and USP No. 2003/0047727 (Patent Document 3). In each of the known examples, a conductor such as Ti is used, for example, as a specific material for the adhesion layer. FIG. 6 shows a cross sectional structure of a memory cell in a case of forming an adhesion layer comprising a conductor over a plug and an inter-layer insulative film. Since the conductor adhesion layer 8 is disposed over the entire interface between the chalcogenide material layer 3 and the inter-layer insulative film 1, the chalcogenide material layer can be prevented from separation. However, in this structure, when a voltage is applied from the plug 2 upon rewriting operation of the phase change memory, since the resistivity of the conductor adhesion layer 8 is lower than that of the chalcogenide material layer 3, current flows mainly in the lateral direction of the adhesion layer (direction parallel with the surface of a substrate). In this case, since the region of the chalcogenide material layer that is heated by the Joule heat prevails over the entire surface for the portion in contact with the adhesion layer 8, an extremely large current is necessary for crystallization or amorphization of the chalcogenide material layer.

The problem described above can be solved by forming a conductor adhesion layer 8 only in the region not in contact with the plug 2 as shown in FIG. 7. In this case, since the region of the chalcogenide material layer 3 heated by the Joule heat is restricted to the portion in contact with the plug 2, the current necessary for crystallization or amorphization of the chalcogenide material layer 3 is decreased compared with a case of FIG. 6. However, since a region not provided with the adhesion layer is present between the chalcogenide material layer 3 and the inter-layer insulative film 1, separation of the chalcogenide material layer can not be prevented completely. Further, after formation of the conductor adhesion layer 8 over the entire surface of the substrate including the portion over the inter-layer insulative film 1 and the plug 2, an additional step of removing the conductor adhesion layer over the plug 2 is necessary. In this case, the number of masks increases to increase the manufacturing cost and the aligning margin decreases in a case of miniaturizing the memory cell, resulting in a problem of lowering the yield or the reliability.

Therefore, means capable of preventing the separation of the chalcogenide material layer with no undesired effect on the rewriting characteristic of the phase change memory has been demanded.

The second subject is that an extremely large current is necessary for heating the chalcogenide material layer by the Joule heat when a low resistance material, for example, tungsten is used for the plug since the heat tends to escape from the chalcogenide material layer by way of the plug. This is attributable to that a material of low resistivity generally has high heat conductivity. In particular, since the chalcogenide material has to be heated to the melting point or higher upon resetting (amorphization), heat diffusion from the plug produces a significant problem.

For example, for embedding with a logic circuit, a current necessary for rewiring has to be decreased at least to such an extent as capable of operation with a MOS transistor. To enable rewriting at low current, it is necessary to use a structure capable of suppressing heat diffusion from the plug and efficiently heating the chalcogenide material layer. In a case of an optical disk, since writing/reading is made by a laser, a portion electric connection with the chalcogenide material layer is not necessary. Accordingly, it is free from contact with a material of high heat conductivity. That is, heat diffusion by way of a material of high heat conductivity is a problem inherent to the phase change memory that makes writing/reading with electric pulses.

To suppress the heat diffusion from the plug, means has been proposed for using a material with high resistivity, that is, low heat conductivity for the plug. A known example of applying a high resistance material to the plug includes, for example, JP-A No. 2003-174144 (Patent Document 1). Specific examples of a high resistance plug material include TiSiN, TiAlN, and TiSiC to be used. In this case, a new material not used in existent logic circuits has to be introduced, resulting in a problem of increasing the manufacturing cost and lowering the yield and reliability.

Therefore, means capable of suppressing heat diffusion even by the use of an existent plug of low resistance material has been demanded. Since this can heat the chalcogenide material efficiently, the current for rewriting the phase change memory can be lowered.

Outlines of typical inventions among those disclosed in the present application are to be described briefly as below.

At first, a semiconductor storage device includes a semiconductor substrate, a selection transistor formed on a main surface of the semiconductor substrate, an inter-layer insulative film disposed over the selection transistor, a plug selectively disposed to pass through the inter-layer insulative film and connected electrically with the selection transistor, a chalcogenide material layer connected to one end of the plug and disposed so as to extend over the inter-layer insulative film, an upper electrode disposed over the chalcogenide material layer, and an interfacial layer formed between the chalcogenide material layer and the inter-layer insulative film so as to cover at least one end of the plug and comprising a continuous insulator not having a region where the chalcogenide material layer and the inter-layer insulative film are not in direct contact with each other.

Secondly, a semiconductor storage device includes a semiconductor substrate, a selection transistor formed on a main surface of the semiconductor substrate, an inter-layer insulative film disposed over the selection transistor, a plug selectively disposed to pass through the inter-layer insulative film and connected electrically with the selection transistor, a chalcogenide material layer connected to one end of the plug and disposed so as to extend over the inter-layer insulative film, an upper electrode disposed over the chalcogenide material layer, and an interfacial layer formed between the chalcogenide material layer and the inter-layer insulative film so as to cover at least one end of the plug and comprising a continuous semiconductor not having a region where the chalcogenide material layer and the inter-layer insulative film are not in direct contact with each other.

Thirdly, a semiconductor storage device includes; a semiconductor substrate, a selection transistor formed on a main surface of the semiconductor substrate, an inter-layer insulative film disposed over the selection transistor, a plug selectively disposed to pass through the inter-layer insulative film and connected electrically with the selection transistor, a chalcogenide material layer connected to one end of the plug and disposed so as to extend over the inter-layer insulative film, an upper electrode disposed over the chalcogenide material layer, and an adhesion layer comprising a semiconductor formed between the chalcogenide material layer and the inter-layer insulative film, and an interfacial layer formed between the chalcogenide material layer and the plug and comprising an alloy of the adhesion layer material and the plug material.

According to the invention, separation of the chalcogenide material layer during the manufacturing step can be suppressed. Further, upon rewriting operation of the phase change memory, escape of heat from the chalcogenide material layer heated by joule heat by way of the plug of high heat conductivity can be suppressed.

As a result, nonuniformity of electric characteristics and deterioration of reliability attributable to the manufacturing steps of the phase change memory can be suppressed and, further, the current for rewriting can be lowered to such an extent as capable of operating with a MOS transistor by improving the efficiency of heat generation.

### BRIEF DESCRIPTION OF THE DRAWINGS

FIG. 1 is a cross sectional view of a phase change memory cell according to the invention;

FIG. 2 is a graph showing a current pulse specification for changing the phase state of chalcogenide;

FIG. 3 is a step chart for the cross section of a main portion of a phase change memory cell in the conventional art;

FIG. 4 is a step chart for the cross section of a main portion of a phase change memory cell in the conventional art;

FIG. 5 is a step chart for the cross section of a main portion of a phase change memory cell in the conventional art;

FIG. 6 is a cross sectional view of a phase change memory cell in the conventional art;

FIG. 7 is a cross sectional view of a phase change memory cell in the conventional art;

FIG. 8 is a graph showing the calculations of separation energy through molecular dynamics;

FIG. 9 is a graph showing the calculations of separation energy through molecular dynamics;

FIG. 10 is a graph showing the calculations of separation energy through molecular dynamics;

FIG. 11 is a graph showing the calculations of separation energy through molecular dynamics;

FIG. 12 is a cross sectional view of a phase change memory cell according to the invention;

FIG. 13 is a cross sectional view of a phase change memory cell according to the invention;

FIG. 14 is a cross sectional view of a phase change memory cell according to Embodiment 1;

FIG. 15 is a cross sectional view of a phase change memory cell according to Embodiment 2;

FIG. 16 is a cross sectional view of a phase change memory cell according to Embodiment 3;

FIG. 17A is a step chart for the cross section of a plug portion upon formation of an insulator interfacial layer according to the conventional art;

FIG. 17B is a step chart for the cross section of a plug portion upon formation of an insulator interfacial layer according to the conventional art;

FIG. 18A is a step chart for the cross section of a plug portion upon formation of an insulator interfacial layer according to the invention;

FIG. 18B is a step chart for the cross section of a plug portion upon formation of an insulator interfacial layer according to the invention;

FIG. 19 is a cross sectional view of a phase change memory cell according to Embodiment 4;

FIG. 20A is a distribution for set resistance and reset resistance of a phase change memory according to the conventional art; and

FIG. 20B is a distribution of set resistance and reset resistance of a phase change memory cell according to the invention.

### DESCRIPTION OF THE PREFERRED EMBODIMENTS

The present invention is to be described specifically by way of preferred embodiments with reference to the drawings. Through out the drawings for explaining preferred embodiments, members having identical functions carry the same reference numerals, for which duplicate descriptions are to be omitted. Further, in the following descriptions, typical means for solving the foregoing two problems simultaneously are at first described, and more concrete embodiments are to be described subsequently.

A first means in the invention is to form a continuous interfacial layer comprising an insulator between the lower surface of a chalcogenide material layer and the upper surface of an inter-layer insulative film and a plug.

Heretofore, conductor materials such as Ti and Al have been used as an adhesive layer. This is because conductor materials tend to react with a chalcogenide material, which strengthens the bonding force at the interface to improve the separation resistance. However, the inventors have found that peeling of the chalcogenide material layer can be suppressed by using not only conductor materials but also insulator materials for the adhesive layer. This is because even the insulator material reacts slightly with the chalcogenide material to enhance the bonding strength and, in addition, the insulator material has high resistance to the dry etching process. The result of experiment is to be described specifically.

The molecular dynamics calculations for the interface-peeling strength are shown in FIGS. 8 to 11. GeSbTe (herein after referred to as GST) is assumed as the chalcogenide material and energy necessary for peeling a GST film at the interface relative to the underlying material to be bonded was calculated. This energy is defined as separation energy. In a case where the underlying material is crystals, a crystal phase that tends generally to be oriented is assumed. For example, since (001) phase tends to grow in the direction parallel with a substrate plane in Ti, a separation energy between GST and Ti (001) interface was determined.

During manufacturing steps of a phase change memory, a peeling possibility is high when the chalcogenide material layer is patterned by a dry etching method in the structure, for example, as shown in FIG. 4. Since the dry etching method is often implemented in a Cl or F containing atmosphere, it is likely that Cl or F diffuses to the interface between GST and the underlying material. Then, the separation energy was also determined by calculation in a case of assuming that Cl or F diffuses by 1 at % to the interface between GST and the underlying material.

At first, the result of FIG. 8 is to be described. It can be seen that the separation energy is extremely small in a case where the underlying material is amorphous SiO₂ (a-SiO₂) compared with the case of Ti (001), TiN (111), or Al (111). This is a result of supporting the fact that the interface between GST and a-SiO₂ tends to be separated. Further, it can be seen that the separation energy is further lowered when Cl or F is present at the interface between GST and a-SiO₂. In view of the above, it is probable that when GST is patterned by a dry etching method, GST tends to be separated by the diffusion of Cl or F at the interface between GST and the inter-layer insulative film.

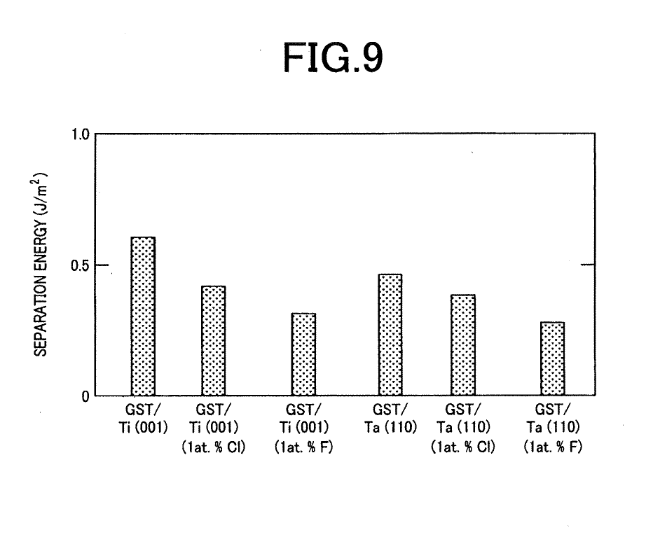

Then, the result of FIG. 9 is to be described. It is likely that the separation energy is relatively high at the interface between GST and Ti (001) and at the interface between GST and Ta (110), causing less separation. However, it can be seen that the separation energy is lowered remarkably when Cl or F is present at the interface. However, it is probable that, even when Cl or F diffuses to lower the separation energy, since the separation energy is still high compared with that at the interface with a-SiO₂ shown in FIG. 8, this functions as an adhesive layer. However, in a case of using a conductor such as Ti or Ta for the adhesive layer, an extremely large current is necessary for rewriting the chalcogenide material layer as described above.

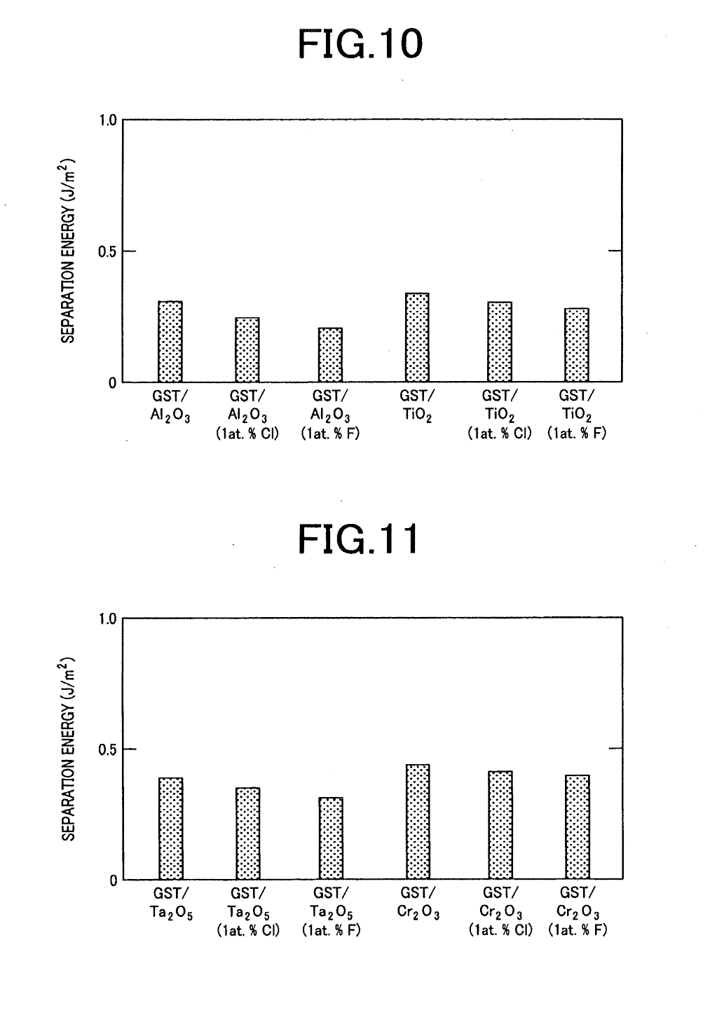

Then, the result of FIG. 10 is to be described. It can be seen that the separation energy at the interface between GST and Al₂O₃ and at the interface between GST and TiO₂ is lower compared with the conductor such as Ti or Ta shown in FIG. 9, but it is higher compared with that at GST/a-SiO₂ shown in FIG. 8. Further, the separation energy is less lowered, when Cl or F is present at the interface, compared with GST/a-SiO₂ shown in FIG. 8. The results show that the insulator material such as Al₂O₃ or TiO₂ has high resistance to the dry etching process, and it is probable that it is desirable as the adhesive layer.

Then, the result of FIG. 11 is to be described. The separation energy at the interface between GST and Ta₂O₅ and at the interface between GST and Cr₂O₃ is higher compared with that for Al₂O₃ or TiO₂ shown in FIG. 10. Further, the separation energy when Cl or F is present at the interface is higher also compared with that for the conductor such as Ti or Ta shown in FIG. 9. The result shows that Ta₂O₅ or Cr₂O₃ is extremely desirable as the adhesive layer.

Among the materials studied in this case, as the adhesive layer of the insulative, Cr₂O₃ is most desirable, Ta₂O₅ is next to the best, followed by TiO₂ and Al₂O₃ in this order.

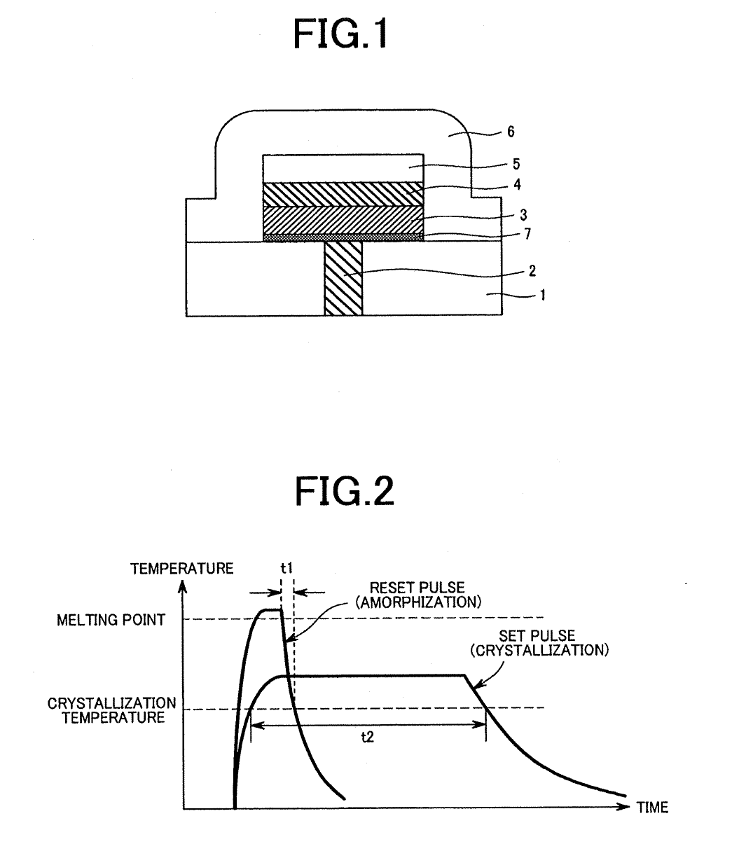

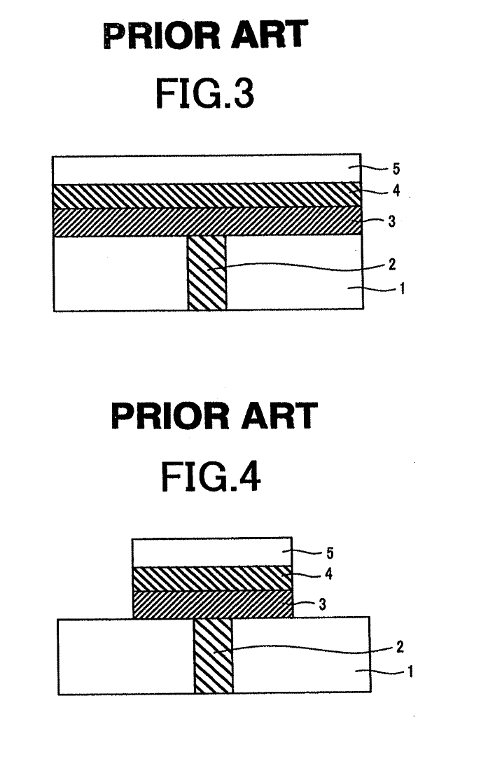

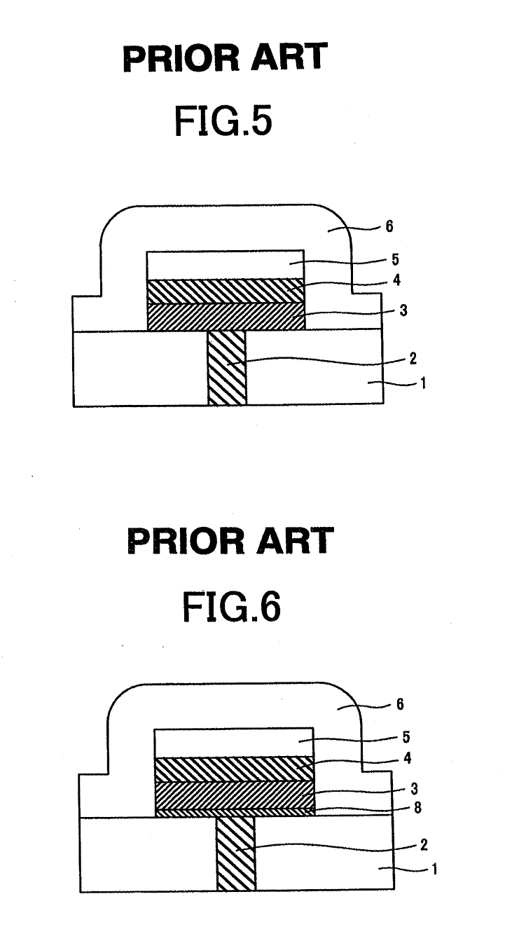

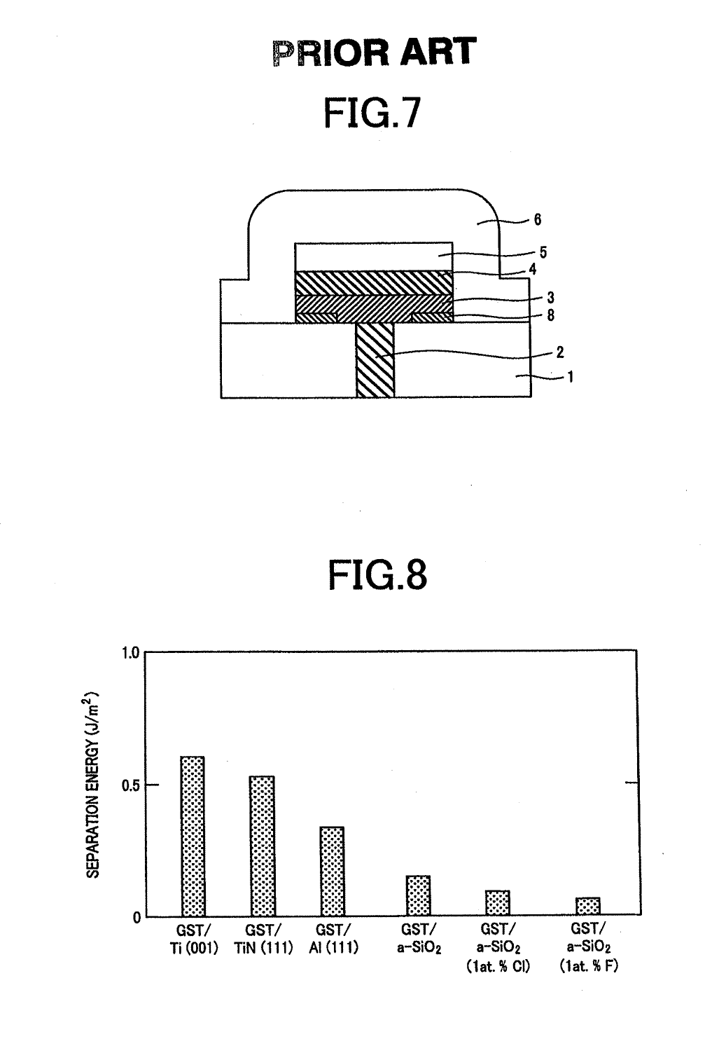

An example of the manufacturing step using the invention is to be described with reference to FIG. 1. An inter-layer insulative film 1 and a plug 2 are formed by the same method as in the related art. Then, an insulator interfacial layer 7 comprising, for example, a tantalum oxide, a chalcogenide material layer 3 comprising, for example, GeSbTe, an upper electrode 4 comprising, for example, tungsten, and a hard mask 5 comprising, for example, a silicon oxide film are deposited in this order. Then, the hard mask 5, the upper electrode 4, the chalcogenide material layer 3, and the insulator interfacial layer 7 are patterned by the well-known lithographic method and dry etching method. Then, the inter-layer insulative film 6 is deposited as shown in FIG. 1.

According to the means described above, since the adhesive layer comprising the insulator is formed over the entire lower surface of the chalcogenide material layer, the peeling strength is increased to suppress separation during the manufacturing step.

Further, according to the invention, since the interfacial layer comprising the insulator is formed over the plug, diffusion of heat from a low resistance plug can be suppressed. This is because the insulator material has lower heat conductivity compared with the conductor material. For example, while the heat conductivity of tungsten as the conductor is 1.74 W/cm·K (@27° C.), the heat conductivity of the titanium oxide as the insulator is as low as 6.5×10⁻² W/cm·K (@100° C.), i.e., about two digits. Accordingly, in a case of inserting an interfacial layer comprising the insulator between the chalcogenide material layer and the plug, heat can be suppressed from escaping from the chalcogenide material layer through the plug. As a result, since the chalcogenide material can be heated efficiently, current for rewriting the phase change memory can be lowered.

As can be seen from the forgoing descriptions, according to the invention, the adhesion of the chalcogenide material layer is low; therefore, the problem in that the film tends to separate from the substrate during the manufacturing step of the phase change memory can be solved together with the problem in that the extremely large current is necessary for heating the chalcogenide material layer by joule heat since the heat is liable to escape from the chalcogenide material layer through the plug.

It is necessary that the film thickness of the interfacial layer comprising the insulator is at least larger than the film thickness to form a continuous film. In a case where the interfacial layer is not a continuous film but an island-like film, it does not function as the adhesive layer on the inter-layer insulative film and does not function as the heat resistance layer also on the plug. Depending on the material of the interfacial layer, the interfacial layer preferably has a film thickness of 0.5 nm or more in order to be formed as a continuous film.

The interfacial layer comprising the insulator may be either amorphous or polycrystal. For example, while polycrystal has crystal grain boundaries present in the film, this can also be regarded as a continuous film in the light of the gist of the invention.

Further, it is necessary that the interfacial layer comprising the insulator should have a film thickness less than that of the insulative film through which a tunnel current flows. To heat the chalcogenide layer to a melting point or higher by the joule heat, a necessary current has to flow from the plug to the chalcogenide material layer. When the thickness of the interfacial layer comprising the insulator increases, since the electric resistance increases to decrease the amount of current, it is necessary that the insulator interfacial layer is made as thin as possible. Generally, the series resistance of the insulator film increases exponentially relative to the film thickness. It is known that a current of about 100 μA to 1 mA is necessary in order to heat the chalcogenide material layer to a melting point or higher. For example, in order to generate a current of 100 μA at a voltage of 3 V, it is necessary that the resistance of the interfacial layer be decreased to at least 30 kΩ or less. In order to attain the series resistance of 30 kΩ or less by using the insulator film, the film thickness has to be reduced up to a region where a tunnel current is predominant. For this purpose, it is necessary that the film thickness is at least 5 nm or less and, in order to obtain a sufficiently large current, the film thickness is desirably 3 nm or less.

It may suffice that the material for the interfacial layer comprising the insulator has higher adhesion with the chalcogenide material layer than the inter-layer insulative film material (for example, silicon oxide film) and less heat conductivity than the plug material (for example, tungsten). For example, the material includes a Ti oxide film, Zr oxide film, Hf oxide film, Ta oxide film, Nb oxide film, Cr oxide film, Mo oxide film, W oxide film, and Al oxide film.

The second means of the invention is to form a continuous interfacial layer comprising a semiconductor between the lower surface of the chalcogenide material layer and the upper surface of the inter-layer insulative film and the plug.

The inventors have found that peeling of the chalcogenide material layer can be suppressed also by using the semiconductor material for the adhesive layer. This is because the bonding strength is increased extremely when Si is used for example as the adhesive material and GeSbTe is used for example as the chalcogenide material layer since Si and Ge tend to take place substitution reaction.

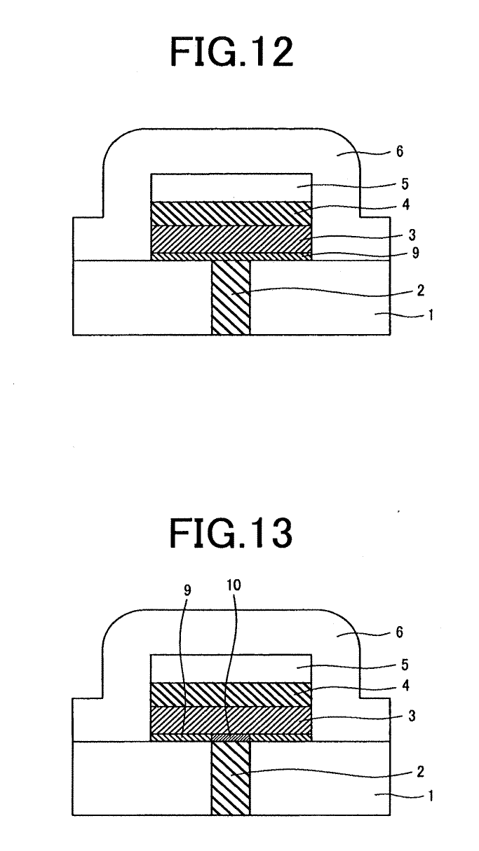

An example of the manufacturing step adopting the invention is to be described with reference to FIG. 12. An inter-layer insulation film 1 and a plug 2 are formed in the same manner as in the conventional art. Then, a semiconductor interfacial layer 9 comprising, for example, amorphous silicon, a chalcogenide material layer 3 comprising, for example, GeSbTe, an upper electrode 4 comprising, for example, tungsten, and a hard mask 5 comprising, for example, silicon oxide film are deposited in this order. Then, the hard mask 5, the upper electrode 4, the chalcogenide material layer 3, and the semiconductor interfacial layer 9 are patterned by a well-known lithographic method and dry etching method. Then, the interlayer insulative film 6 is deposited as shown in FIG. 12.

According to the means, since the adhesive layer comprising the semiconductor is formed over the entire lower surface of the chalcogenide material layer, the peeling strength is increased to suppress peeling during the manufacturing step.

Further, according to the invention, since the interfacial layer comprising the semiconductor is formed over the plug, heat diffusion from the low resistance can be suppressed. This is because the heat conductivity of the semiconductor material is less than that of the conductor material. For example, upon comparison at 1000° C.K which is about the melting point of GeSbTe, the heat conductivity of tungsten as the conductor is 1.18 W/cm·K, whereas the heat conductivity of silicon as the semiconductor is as small as 0.312 W/cm·K, i.e., about ¼. Accordingly, when the interfacial layer comprising the semiconductor is inserted between the chalcogenide material layer and the plug, dissipation of heat from the chalcogenide material layer through the plug can be suppressed. As a result, since the chalcogenide material can be heated efficiently, current for rewiring the phase change memory can be lowered.

As apparent from the forgoing descriptions, according to the invention, the adhesion of the chalcogenide material layer is low; therefore, the problem in that the film tends to be separated from the substrate during the manufacturing step of the phase change memory can be solved together with the problem in that the extremely large current is necessary for heating the chalcogenide material layer by joule heat since heat is liable to escape from the chalcogenide material layer through the plug.

It is necessary that the film thickness of the interfacial layer comprising the semiconductor is at least larger than the film thickness to form a continuous film. In a case where the interfacial layer is not a continuous film but an island-like film, it does not function as the adhesive layer on the inter-layer insulative film and does not function as the heat resistance layer also on the plug. Depending on the material of the interfacial layer, the interfacial layer preferably has a film thickness of 0.5 nm or more in order to be formed as a continuous film.

The interfacial layer comprising the semiconductor may be either amorphous or polycrystal. For example, while polycrystal has crystal grain boundaries present in the film, this can also be regarded as a continuous film in the light of the gist of the invention.

However, since the resistance of polycrystal is lower than that of amorphous, when a voltage is applied from the plug during the rewriting operation for the phase change memory, current tends to flow in the lateral direction of the adhesive layer (in the direction parallel with the substrate surface). Then, since the region of the chalcogenide material layer heated by the Joule heat is enlarged, a further larger current is necessary for crystallizing or amorphizing the chalcogenide material layer. Accordingly, amorphous is preferred to the polycrystal for the interfacial layer comprising the semiconductor.

Further, it is desirable not to add an impurity to the interfacial layer comprising the semiconductor. It has been known that the electroconductivity increases when an impurity, for example, p (phosphorus), As (arsenic), Sb (antimony), or B (boron) is added into silicon. In this case, the resistance of the interfacial layer lowers to require a larger current for rewriting the chalcogenide material layer. However, since the resistance less lowers unless the impurity is activated, the effect of adding the impurity is small in a case of using the amorphous semiconductor interfacial layer.

Further, it is necessary that the thickness of the interfacial layer comprising the semiconductor is such that the resistance in the vertical direction (direction perpendicular to the substrate surface) is sufficiently lower than the resistance in the lateral direction (direction parallel with the substrate surface). In a case where the resistance in the lateral direction (direction parallel with the substrate surface) is low, when a voltage is applied from the plug upon rewriting operation for the phase change memory, the current flows in the lateral direction mainly through the interfacial layer. In this case, since the region where the chalcogenide material layer is heated by the Joule heat prevails for the entire surface for the portion in contact with the interfacial layer, an extremely large current is necessary for rewriting the chalcogenide material layer. When the thickness of the semiconductor interfacial layer is made as thin as possible to lower the resistance in the vertical direction (direction perpendicular to the substrate surface), since the current tends to flow from the plug through the semiconductor interfacial layer in the vertical direction, the current does not prevail in the lateral direction. Then, since the region of the chalcogenide material layer is heated by the Joule heat restricted to the vicinity of the plug, the current necessary for rewriting the chalcogenide material layer can be decreased. It is necessary that the thickness of the semiconductor interfacial layer is at least 5 nm or less and, in order to obtain a sufficiently large current, the film thickness is desirably 3 nm or less.

It may suffice that the material for the interfacial layer comprising the semiconductor is a material having a higher adhesiveness with the chalcogenide material layer than the inter-layer insulative film material (for example, silicon oxide film) and lower heat conductivity than the plug material (for example, tungsten). The material includes, for example, Si, Ge, or SiC. Among them, Si is the most desirable material since it is highly reactive with GeSbTe and has high compatibility with the conventional art.

When the interfacial layer of the semiconductor material is used, the interfacial layer material and the plug material may sometimes react with each other during the manufacturing step of the phase change memory. An example of the manufacturing step in this case is to be described with reference to FIG. 13. An inter-layer insulative film 1 and a plug 2 comprising, for example, tungsten is formed in the same manner as in the conventional art. Then, a semiconductor interfacial layer 9 comprising, for example, amorphous silicon, a chalcogenide material layer 3 comprising, for example, GeSbTe, an upper electrode 4 comprising, for example, tungsten, and a hard mask 5 comprising, for example, a silicon oxide film are deposited in this order. When the temperature upon deposition of the hard mask 5 comprising the silicon oxide film is increased, the tungsten plug 2 and the amorphous silicon interfacial layer react with each other to form a silicide interfacial layer 10 comprising tungsten silicide. Then, the hard mask 5, the upper electrode 4, the chalcogenide material layer 3, and the semiconductor interfacial layer 9 are patterned by a well-know lithographic method and dry etching method. Then, the inter-layer insulative film 6 is deposited as shown in FIG. 13.

According to the means, since the adhesive layer comprising the semiconductor is formed over the entire lower portion of the chalcogenide material layer, the separation strength is increased and the separation during the manufacturing step can be suppressed.

Further, according to the invention, since the interfacial layer comprising silicide is formed over the plug, heat dissipation from the plug can be suppressed. As a result, since the chalcogenide material can be heated efficiently, the current for rewriting the phase change memory can be lowered.

As apparent from the forgoing descriptions, when the semiconductor material is used as the interfacial layer, the problem in that the film tends to be separated from the substrate during the manufacturing step of the phase change memory and the problem in that the heat tends to dissipate from the chalcogenide material layer through the plug can be solved simultaneously even when the semiconductor material reacts with the plug material during the manufacturing step.

Then, the preferred step for forming a continuous interfacial layer comprising the insulator between the lower surface of the chalcogenide material layer and the upper surface of the inter-layer insulative film and the plug as the first means of the invention is to be described specifically. In a case where the continuous interfacial layer comprising the insulator is formed between the lower surface of the chalcogenide material layer and the upper surface of the inter-layer insulative film as in the first means, it is necessary that the thickness of the insulator has to be decreased to such an extent as a tunnel current flows. Further, since the current flows through the insulator, the device characteristic changes greatly when the film thickness varies, so that the film thickness has to be uniform.

For example, in a case of forming a tantalum oxide film as the interfacial layer material, a method of sputtering in an oxidative atmosphere by using a tantalum metal target is generally used. Since tantalum oxide is formed by the oxidation of the surface of the tantalum metal target by reaction with oxygen in a gas phase, this method is referred to as a reactive sputtering method. According to the general reactive sputtering method, the distribution of the film thickness of the tantalum oxide is about 5% at 1 σ. Since the series resistance of the insulator changes exponentially relative to the film thickness, the dispersion in the film thickness of 5% causes dispersion of resistance by one digit or more.

Further, use of the reactive sputtering method also results in a problem of oxidation on the plug surface. This is to be explained with reference to FIG. 17. By using a well-known manufacturing method, an inter-layer insulative film 1 comprising, for example, a silicon oxide film is deposited, and a plug 11 comprising, for example, tungsten is formed inside the inter-layer insulative film 1 (FIG. 17A). The plug has a function of electrically connecting a selecting transistor on the lower side and a phase changing material layer on the upper side. Then, when a interfacial layer 12 comprising, for example, a tantalum oxide film is deposited by using the reactive sputtering method of the conventional art, the surface of the tungsten plug is oxidized by oxygen plasma in the sputtering atmosphere to form a tungsten oxide film 13 (FIG. 17B). As a result, the interfacial layer on the tungsten plug has a layered structure of the tungsten oxide film 12 and the tungsten oxide film 13. It has been known that the resistance of the tungsten oxide film varies greatly depending on the film quality, causing dispersion of resistance.

That is, in a case of forming a continuous interfacial layer comprising the insulator is formed between the lower surface of the chalcogenide material layer and the upper surface of the inter-layer insulative film and the plug, when the insulative film is formed by using the general reactive sputtering method, this may possibly cause an additional problem of increasing the in-plane scattering of the resistance.

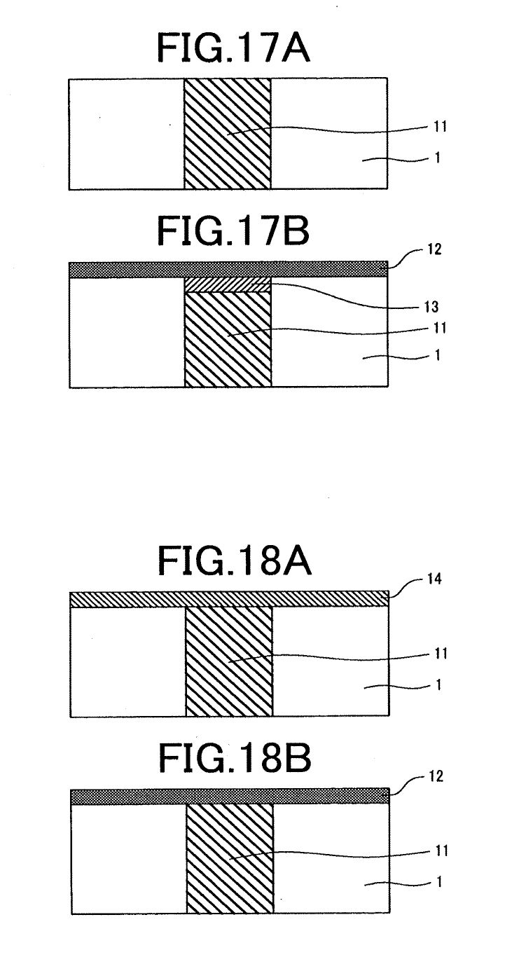

Then, as a method of forming the insulator interfacial layer, the invention adopts means for forming a metal film by sputtering using a metal target and then oxidizing the metal film in an oxidative atmosphere such as oxygen radicals or oxygen plasma. This is to be described with reference to FIG. 18. In the same means as in FIG. 17, a plug 11 comprising, for example, tungsten is formed inside an inter-layer insulative film. Then, by using a well-known sputtering method, a tantalum metal film 14, for example, is deposited (FIG. 18A). Then, a tantalum oxide film 12 is formed by oxidizing the tantalum metal film 14 by oxygen radicals (FIG. 18B). By the use of the means, an interfacial layer comprising the tantalum oxide film can be formed without oxidizing the surface of the tungsten plug by optimizing the radical oxidation time. That is, formation of the tungsten oxide film that would cause the dispersion of resistance can be prevented.

Further, in the sputtering method, the uniformity of the film thickness can be enhanced by depositing the metal film rather than by depositing the oxide film. Accordingly, the uniformity of the film thickness can be improved more by post-oxidizing the tantalum metal film to form a tantalum oxide film rather than by forming the tantalum oxide film by the reactive sputtering method. That is, the dispersion of the thickness of the tantalum oxide film causing the dispersion of the resistance can be decreased.

As apparent from the foregoing descriptions, by the use of means for forming the metal film by sputtering using a metal target and then oxidizing the metal film in an oxidative atmosphere such as oxygen radicals or oxygen plasma, as the method of forming the insulator interfacial layer, the uniformity of the oxide film thickness can be improved. Specifically, the distribution for the thickness of the tantalum oxide film is 1% or less at 1 σ. As a result, the dispersion of the resistance can be controlled to at least one digit or less.

In order to further enhance the uniformity for the thickness of the insulator interfacial layer, it is at first necessary to apply a device to formation of the uniform metal film. Means desirable therefor are set forth below. Not all of the means are necessary but they may be selected optionally while considering necessary specification and cost. The first is that the ultimate pressure in a sputtering chamber is high. It is desirable that an ultra high vacuum of 10⁻⁶ Pa or less be attainable. The second is that the electric discharge pressure is low. It is preferred to make discharge at 0.1 Pa or lower. The third is that the distance between the target and the substrate is long. It is preferred to space them 15 cm or more apart. The fourth is to conduct film formation while rotating the substrate.

Then, it is necessary to apply a device for uniformly oxidizing the metal film. For this purpose, an oxidant and an oxidizing temperature capable of providing a controllable oxidation rate have to be selected. Generally, it is desirable to conduct oxidation at room temperature by using oxygen radicals. Depending on the material for the metal film, of course it may be desirable to use oxygen or oxygen plasma for the oxidant in some cases, and it may also be desirable to conduct oxidizing treatment under heating. Further, it is preferred to conduct the step of oxidizing the metal film continuously with no exposure to atmospheric air by transporting substrates in a vacuum after the step of forming the metal film.

By adopting the means described above optionally, the distribution for the thickness of the tantalum oxide film can be suppressed, specifically, to 0.5% or less at 1 σ.

### Embodiment 1

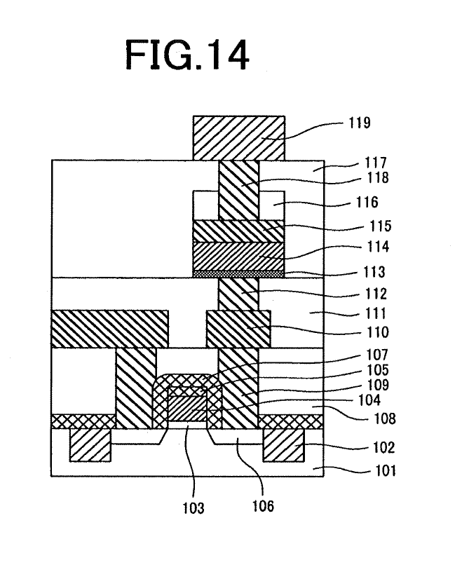

Embodiment 1 of the present invention is to be described with reference to FIG. 14. In this embodiment, a continuous interfacial layer comprising an insulator is formed between the lower surface of a chalcogenide material layer and the upper surface of an inter-layer insulative film and a plug. This specifically shows first means for forming a phase change memory cell in the semiconductor memory device of the invention by way of example.

At first, a semiconductor substrate 101 is provided and an MOS transistor used as a selection transistor is prepared. For this purpose, a device isolation oxide film 102 for isolating an MOS transistor is formed by using a well-known selective oxidation method or shallow trench isolation method. In this embodiment, the shallow trench isolation method capable of planarizing the surface is used.

At first, an isolation trench is formed in a substrate by using a well-know dry etching method and, after removal of any damage to the trench side wall or the bottom caused by dry etching, an oxide film is deposited by using a well-known CVD method and an oxide film at portions other than the trench is polished selectively also by a well-known CMP method while leaving only the device isolation oxide film 102 buried in the trench.

Then, although not illustrated in the figure, wells of two conduction types different from each other are formed by implantation of impurities at high energy.

Then, after cleaning of the surface of the semiconductor substrate, a gate oxide film 103 of the MOS transistor is grown by a well-known thermal oxidation method. A gate electrode 104 comprising polycrystal silicon and a silicon nitride film 105 are deposited on the surface of the gate oxide film 103. Successively, after patterning the gate by a lithographic step and a dry etching step, impurities are implanted by using the gate electrode and a resist as a mask to form a diffusion layer 106. In this embodiment, while the polycrystal silicon is used as the gate electrode 104, a polymetal gate as a laminate structure of metal/barrier metal/polycrystal silicon can also be used as a low resistance gate.

Then, for application of self-alignment contact, a silicon nitride film 107 is deposited by a CVD method.

Then, an inter-layer insulative film 108 comprising a silicon oxide film is deposited over the entire surface, and the surface roughness attributable to the gate electrode 104 is planarized by using a well-known CMP method (chemical-mechanical polishing method).

Successively, a plug contact hole is opened by a lithographic step and a dry etching step. In this case, to avoid the exposure of the gate electrode, the inter-layer insulative film 108 is patterned under the so-called self alignment condition, that is, a condition of providing higher selectivity to the silicon oxide film relative to the silicon nitride film.

As a countermeasure of miss-alignment of the plug contact hole with the diffusion layer 106, it is possible to adopt the steps of: dry etching the inter-layer insulative film 108 under the conditions of providing higher selectivity to the silicon oxide film relative to the silicon nitride film, thereby leaving the silicon nitride film on the upper surface of the diffusion layer 106; and, successively, dry etching the film under the conditions of providing higher selectivity to the silicon nitride film relative to the silicon oxide film thereby removing the silicon nitride film on the upper surface of the diffusion layer 106.

Successively, tungsten is buried in the plug contact hole and a tungsten plug 109 is formed by a well-known CUP method.

Then, tungsten is deposited to 100 nm film thickness by a sputtering method and tungsten is patterned by a lithographic step and a dry etching step to form a first inter-connection layer 110. Successively, an inter-layer insulative film 111 comprising a silicon oxide film is deposited over the entire surface, and the surface-roughness attributable to the first inter-connection layer is planarized by using the well-known CMP method.

Successively, a plug contact hole is opened by a lithographic step and a dry etching step. Successively, tungsten is buried in the plug contact hole and a tungsten plug 112 is formed by a well-known CMP method.

Then, an insulator interfacial layer 113 comprising a tantalum oxide film of 2 nm thickness, a chalcogenide material layer 114 comprising GeSbTe of 100 nm thickness, and an upper electrode 115 comprising tungsten of 50 nm thickness are deposited successively by a well-known sputtering method. Then, a silicon oxide film 116 is deposited by a well-known CVD method. Successively, the silicon oxide film 116, the upper electrode 115, the chalcogenide material layer 114, and the insulator interfacial layer 113 are patterned successively by well-known lithographic step and dry etching step.

Then, an inter-layer insulative film 117 comprising a silicon oxide film is deposited over the entire surface and the surface-roughness is planarized by using a well-known CMP method. Successively, a plug contact hole is opened by a lithographic step and a dry etching step. Successively, tungsten is buried in the plug contact hole, and a tungsten plug 118 is formed by a well-known CMP method. Successively, aluminum of 200 nm thickness is deposited and fabricated as an inter-connection layer to form a second inter-connection layer 119. Of course it is possible to use copper of lower resistance instead of aluminum.

By the steps described above, a phase change memory cell of this embodiment is substantially completed as shown in FIG. 14.

According to Embodiment 1, since the adhesion layer comprising the insulator is formed over the entire lower surface of the chalcogenide material layer, the separation strength is increased and separation during the manufacturing step can be suppressed. In addition, since the interfacial layer comprising the insulator is formed over the plug, heat diffusion from the plug made of the low resistance material is suppressed and the chalcogenide material is heated efficiently, the current for rewriting the phase change memory can be lowered.

In the embodiment described above, while the tantalum oxide film was used as the insulator interfacial layer, this is not restrictive but an insulative film such as a titanium oxide film, zirconium oxide film, hafnium oxide film, niobium oxide film, chromium oxide film, molybdenum oxide film, tungsten oxide film, or aluminum oxide film can be used.

Further, as the method of forming the insulator interfacial layer, the oxide film may be formed by sputtering using an oxide target, or the oxide film may also be formed by sputtering in an oxidative atmosphere using a metal target. Further, the oxide film may also be formed by forming a metal film by sputtering using a metal target and then oxidizing the metal film in an oxidative atmosphere such as of oxygen radicals or oxygen plasma.

The composition of the oxide film may not be in the so-called stoichiometrical composition but may be in an oxygen-rich composition or oxygen-depleted composition. For example, referring to a case of a tantalum oxide film, while the stoichiometrical composition is Ta₂O₅, a similar effect can be obtained also in a case where the compositional ratio of oxygen to tantalum is less than or more than 5/2. Further, in a case where the oxygen composition ratio is 5/2 or less, that is in an oxygen depleted composition, since the reactivity with the chalcogenide material layer increases more than in the case of using the tantalum oxide film in a stoichiometrical composition, it is more preferred as the adhesion layer.

In the embodiment described above, while GeSbTe was used as the chalcogenide material layer, this is not restrictive but chalcogenide materials containing at least two elements selected from Ge, Sb, and Te may also be used. Furthermore, chalcogenide materials containing at least two elements selected from Ge, Sb, and Te and at least one element selected from elements belonging to group 2b, group 1b, groups 3a to 7a, and group 8 of the periodical table may also be used.

It will be apparent in the invention that various means described previously are applicable respectively not being restricted only to the embodiment described above.

### Embodiment 2

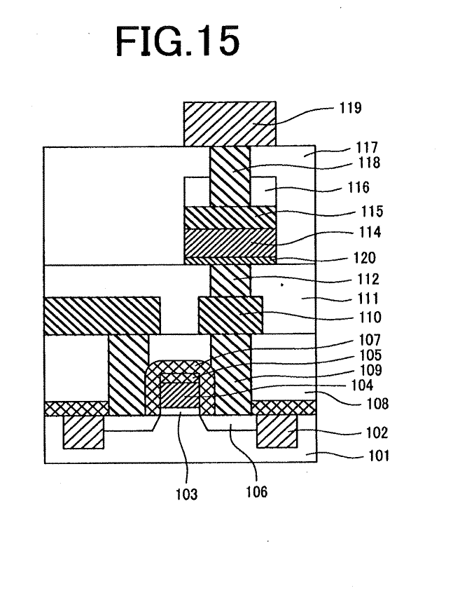

Embodiment 2 of the present invention is to be described with reference to FIG. 15. In this embodiment, a continuous interfacial layer comprising a semiconductor is formed between the lower surface of a chalcogenide material layer and an upper surface of an inter-layer insulative film and a plug. This specifically shows a former half of the second means for forming a phase change memory cell in the semiconductor memory device of the invention by way of example. Since the steps up to the formation of a tungsten plug 112 are identical with those in Embodiment 1, descriptions therefor are to be omitted.

A semiconductor interfacial layer 120 comprising amorphous silicon of 2 nm thickness is deposited over the inter-layer insulative film 111 and a tungsten plug 112 by a well-known CVD method.

Then, a chalcogenide material layer 114 comprising GeSbTe of 100 nm thickness, and an upper electrode 115 comprising tungsten of 50 nm thickness are deposited successively by a well-known sputtering method. Then, a silicon oxide film 116 is deposited by a well-known CVD method. Successively, the silicon oxide film 116, the upper electrode 115, the chalcogenide material layer 114, and the semiconductor interfacial layer 120 are patterned successively by a well-known lithographic step and dry etching step.

Since the subsequent steps are identical with those in Embodiment 1, descriptions therefor are to be omitted.

By the steps described above a phase change memory cell of this embodiment is substantially completed as shown in FIG. 15.

According to Embodiment 2, since an adhesion layer comprising the semiconductor is formed over the entire lower surface of the chalcogenide material layer, the separation strength is increased and separation during the manufacturing step can be suppressed. In addition, since the interfacial layer comprising the insulator is formed over the plug, heat diffusion from the plug made of the low resistance material is suppressed and the chalcogenide material is heated efficiently, the current for rewriting the phase change memory can be lowered.

In the embodiment described above, while amorphous silicon is used as the semiconductor interfacial layer, this is not restrictive but semiconductor films such as of polycrystal silicon, germanium, or silicon carbide can be used.

In the embodiment described above, while GeSbTe is used as the chalcogenide material layer, this is not restrictive but chalcogenide materials containing at least two elements selected form Ge, Sb, and Te may also be used. Furthermore, chalcogenide materials containing at least two elements selected from Ge, Sb, and Te and at least one element selected from elements belonging to group 2b, group 1b, groups 3a to 7a, and group 8 of the periodical table may also be used.

It will be apparent that various means described previously are applicable in the invention not being restricted only to the embodiment described above.

### Embodiment 3

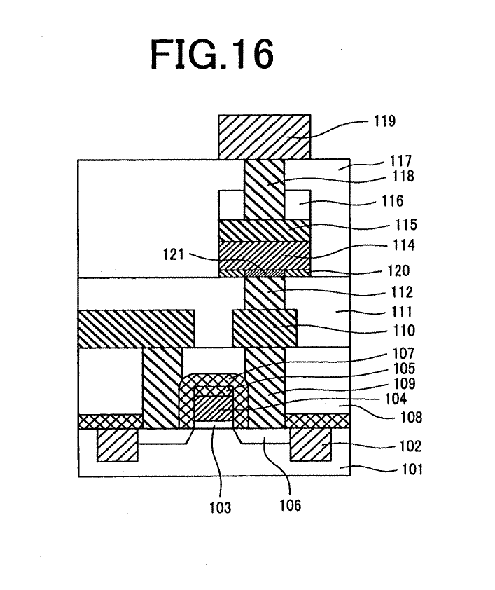

Embodiment 3 of the present invention is to be described with reference to FIG. 16. In this Embodiment, a continuous interfacial layer comprising a semiconductor is formed between the lower surface of a chalcogenide material layer and an upper surface of an inter-layer insulative film and a plug, in which a material for the interfacial layer and the material for the plug react with each other during manufacturing steps of the phase change memory. This specifically shows the latter half portion of the second means for forming the phase change memory cell by way of example.

Since the steps up to the formation of a tungsten plug 112 are identical with those in Embodiment 1, descriptions therefor are to be omitted.

A semiconductor interfacial layer 120 comprising amorphous silicon of 2 nm thickness is deposited by a well-known CVD method over the inter-layer insulative film 111 and a tungsten plug 112 by a well-known CVD method.

Then, a chalcogenide material layer 114 comprising GeSbTe of 100 nm thickness, and an upper electrode 115 comprising tungsten of 50 nm thickness are deposited successively by a well-known sputtering method. Successively, a silicon oxide film 116 is deposited by a well-know CVD method.

A silicide interfacial layer 121 comprising tungsten silicide is formed by setting a temperature upon deposition of the silicon oxide film 116 to 400° C. and reacting the tungsten plug 112 with the semiconductor interfacial layer 120 comprising amorphous silicon.

Successively, the silicon oxide film 116, the upper electrode 115, the chalcogenide material layer 114, and the semiconductor interfacial layer 120 were patterned successively by a well-known lithographic step and dry etching step. Since the subsequent steps are identical with those in Embodiment 1, descriptions are to be omitted. By the steps described above, a phase change memory cell of this embodiment shown in FIG. 16 is substantially completed.

According to Embodiment 3, since the adhesion layer comprising the semiconductor is formed over the entire interface between the chalcogenide material layer and the inter-layer insulative film, the separation strength is increased and separation during the manufacturing step can be suppressed. In addition, since the interfacial layer comprising the silicide is formed at the interface between the chalcogenide material layer and the plug, heat diffusion from the plug of low resistance is suppressed and the chalcogenide material is heated efficiently, the current for rewriting the phase change memory can be lowered.

It will be apparent in the invention that various means described previously in the present specification are applicable not restricted only to the embodiments described above.

### Embodiment 4

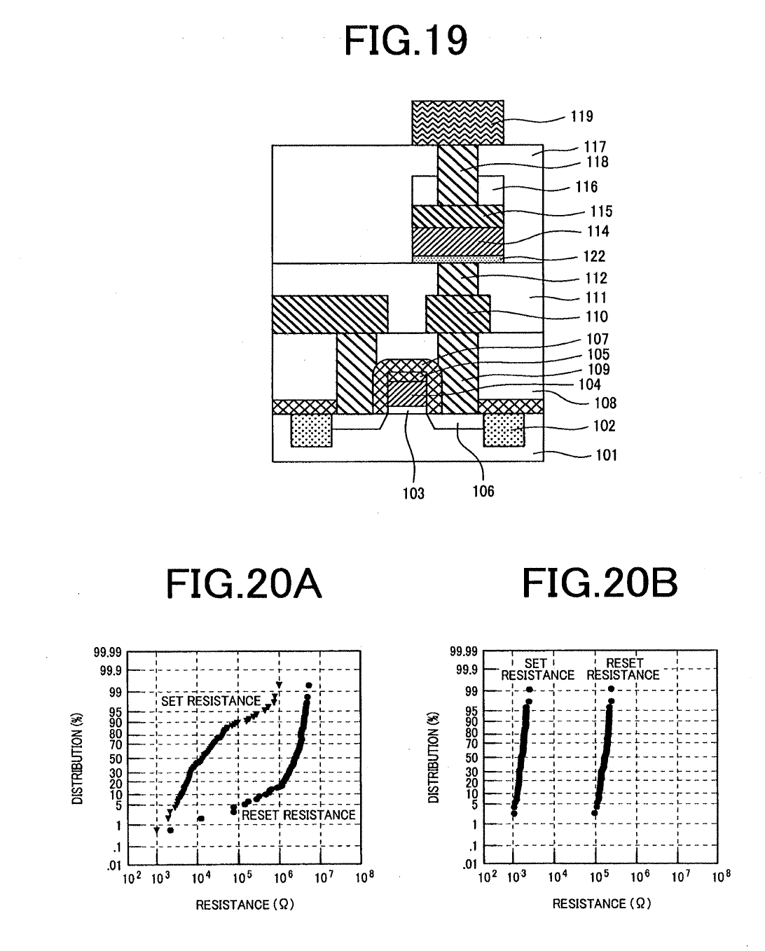

Embodiment 4 of the present invention is to be described with reference to FIG. 19. In this embodiment, a continuous interfacial layer comprising an insulator is formed between the lower surface of a chalcogenide material layer and the upper surface of an inter-layer insulative film and a plug. The embodiment uses, as a method of forming an insulator interfacial layer, means for forming a metal film by sputtering using a metal target and then oxidizing the metal film in an oxidative atmosphere such as of oxygen radicals or oxygen plasma. Since the steps up to the formation of a tungsten plug 112 are identical with those in Embodiment 1, descriptions therefor are to be omitted.

A tantalum metal film of 1 nm thickness was deposited over an inter-layer insulative film 111 and a tungsten plug 112 by sputtering in an argon atmosphere using a tantalum metal target.

Then, the substrate is transported in a vacuum so as not to be exposed to atmospheric air, and the tantalum metal film is subjected to radical oxidation to form a tantalum oxide film interfacial layer 122.

Since the tantalum metal increases in thickness about twice when oxidized, the thickness of the tantalum oxide interfacial layer is about 2 nm.

That is, the thickness of the tantalum metal film may be one-half of a desired thickness of the tantalum oxide film. Further, a tantalum oxide film of a desired thickness may be obtained also by repeating the steps of forming the tantalum metal oxide and oxidizing the same radically a plurality of times.

Then, a chalcogenide material layer 114 comprising GeSbTe of 100 nm thickness and an upper electrode 115 comprising tungsten of 50 nm thickness are deposited successively by a well-known sputtering method. Then, a silicon oxide film 116 is deposited by a well-known CVD method. Successively, the silicon oxide film 116, the upper electrode 115, the chalcogenide material layer 114, and the tantalum oxide film interfacial layer 122 are patterned successively by a well-known lithographic step and dry etching step. Since the subsequent steps are identical with those in Embodiment 1, descriptions therefor are to be omitted. By the steps described above a phase change memory cell of this embodiment is substantially completed as shown FIG. 19.

According to Embodiment 4, since the adhesion layer comprising the insulator is formed over the entire lower surface of the chalcogenide material layer, the separation strength is increased and separation during manufacturing steps can be suppressed. In addition, since the interfacial layer comprising the insulator is formed over the plug, heat diffusion from the plug of the low resistance material is suppressed and the chalcogenide material is heated efficiently, the current for rewriting the phase change memory can be lowered.

Further, as the method of forming the insulator interfacial layer, the uniformity of the thickness of the tantalum oxide film interfacial layer can be improved by using means of sputtering by using a tantalum metal target thereby forming a tantalum metal film, and then oxidizing the tantalum metal film in the oxygen radicals.

FIG. 20 shows the distribution of a set resistance and a reset resistance of phase change memories trial-manufactured by using the conventional art and the present invention.

As a method of forming the tantalum oxide interfacial layer, in a case of using a reactive sputtering method as the conventional art [FIG. 20(A)], since the thickness of the tantalum oxide interfacial layer varies greatly and the oxidation is inevitable for the surface of the tungsten plug, the distribution of the set resistance and the reset resistance is extremely large. On the other hand, in a case of using the means according to the invention [FIG. 20(B)], since the thickness of the tantalum oxide interfacial layer less varies and the oxidation on the surface of the tungsten plug can be suppressed, the distribution of the set resistance and the reset resistance can be evidently suppressed within one digit.

In the embodiment described above, while the tantalum oxide film is used as the insulator interfacial layer, this is not restrictive but an insulative film such as a titanium oxide film, zirconium oxide film, hafnium oxide film, niobium oxide film, chromium oxide film, molybdenum oxide film, tungsten oxide film, or aluminum oxide film can be used.

In the embodiment described above, while GeSbTe is used as the chalcogenide material layer, this is not restrictive but chalcogenide materials containing at least two elements selected form Ge, Sb, and Te may also be used. Furthermore, chalcogenide materials containing at least two elements selected from Ge, Sb, and Te and at least one element selected from elements belonging to group 2b, group 1b, groups 3a to 7a, and group 8 of the periodical table may also be used.

Further, in a case of forming a desired film thickness, for example, to 4 nm for the interfacial layer of the tantalum oxide film, this can be attained also by depositing a tantalum metal film to 1 nm, conducting first oxidation (increasing the film thickness to 2 nm), then, further depositing a tantalum metal film to 1 nm subsequently and applying second oxidation. Depending on the thickness of the tantalum metal film deposited at first, the film can be formed sometimes more rapidly by repeating the process as described above.

It will be apparent that various means described previously are applicable respectively not restricted only to the embodiments described above in the invention.

While the invention made by the present inventor has been described specifically with reference to the embodiments thereof, the invention is not restricted to the embodiments described above, but it will be apparent that the invention can be changed variously within a scope not departing the gist thereof.

What is claimed is:

1. A semiconductor storage device including;
a semiconductor substrate;
a selection transistor formed on a main surface of the semiconductor substrate;
an inter-layer insulative film disposed over the selection transistor;
a plug selectively disposed to pass through the inter-layer insulative film and connected electrically with the selection transistor;
a chalcogenide material layer connected to one end of the plug and disposed so as to extend over the inter-layer insulative film;
an upper electrode disposed over the chalcogenide material layer; and
an interfacial layer formed between the chalcogenide material layer and the inter-layer insulative film so as to cover at least one end of the plug and comprising a continuous semiconductor not having a region where the chalcogenide material layer and the inter-layer insulative film are not in direct contact with each other.

2. A semiconductor storage device according to claim 1, wherein the interfacial layer comprises a material having higher adhesiveness than the inter-layer insulative film relative to the chalcogenide material layer.

3. A semiconductor storage device according to claim 1, wherein the interfacial layer comprises a material of lower heat conductivity than that of the plug.

4. A semiconductor storage device according to claim 1, wherein the interfacial layer comprises a material of higher resistivity than that of the plug.

5. A semiconductor storage device according to claim 1, wherein the interfacial layer has a film thickness of 0.5 nm or more and 5 nm or less and is formed in contact with the lower surface of the chalcogenide material layer.

6. A semiconductor storage device according to claim 1, wherein the interfacial layer comprising a material containing Si.

7. A semiconductor storage device comprising;
a semiconductor substrate;
a selection transistor formed on a main surface of the semiconductor substrate;
an inter-layer insulative film disposed over the selection transistor;
a plug selectively disposed to pass through the inter-layer insulative film and connected electrically with the selection transistor;
a chalcogenide material layer connected to one end of the plug and disposed so as to extend over the inter-layer insulative film;
an upper electrode disposed over the chalcogenide material layer;
an adhesion layer comprising a semiconductor formed between the chalcogenide material layer and the inter-layer insulative film; and
an interfacial layer formed between the chalcogenide material layer and the plug and comprising an alloy of a material of the adhesion layer and a material of the plug.

8. A semiconductor storage device according to claim 7, wherein the adhesion layer and the interfacial layer comprise a material having higher adhesiveness than the inter-layer insulative film relative to the chalcogenide material layer.

9. A semiconductor storage device according to claim 7, wherein the adhesion layer and the interfacial layer comprise a material of lower heat conductivity than the plug.

10. A semiconductor storage device according to claim 7, wherein the adhesion layer and the interfacial layer comprise a material of higher resistivity than the plug.

11. A semiconductor storage device according to claim 7, wherein the adhesion layer and the interfacial layer have a film thickness of 0.5 nm or more and 5 nm or less and are formed in contact with the lower surface of the chalcogenide material layer.

12. A semiconductor storage device according to claim 7, wherein the interfacial layer comprises a material containing Si.

13. A semiconductor storage device including:
a plug;
a phase change material layer formed on the plug; and
an electrode formed on the phase change material layer, wherein the semiconductor storage device stores data according to a phase state of a region of the phase change material layer that is continuous between the plug and the electrode, and
further includes a boundary layer formed between the plug and the phase change material layer and comprised of a semiconductor film having such a thickness that a tunnel current flows.

14. A semiconductor storage device according to claim 13, wherein the phase change material layer contains a chalcogenide material.

15. A semiconductor storage device according to claim 13, wherein the boundary layer has a film thickness of 0.5 nm or more.

16. A semiconductor storage device according to claim 13, wherein the boundary layer has a film thickness of 5 nm or less.

17. A semiconductor storage device according to claim 13, wherein the boundary layer comprises a material containing Si.

18. A semiconductor storage device including:
a plug;
a phase change material layer formed on the plug; and
an electrode formed on the phase change material layer,
wherein the semiconductor storage device stores data according to a phase state of a region of the phase change material layer that is continuous between the plug and the electrode, and
further includes a boundary layer formed between the plug and the phase change material layer and comprised of an alloy of a semiconductor material and a material applying to the plug.

19. A semiconductor storage device according to claim 18, wherein the phase change material layer contains a chalcogenide material.

20. A semiconductor storage device according to claim 18, wherein the boundary layer comprises a material containing Si.
